(19) United States
(12) Patent Application Publication
(10) Pub. No.: US 2024/0145359 A1
(43) Pub. Date: May 2, 2024

(54) WINDOW BALL GRIDE ARRAY (WBGA) PACKAGE STRUCTURE AND METHOD FOR MANUFACTURING THE SAME

(71) Applicant: NANYA TECHNOLOGY CORPORATION, New Taipei City (TW)

(72) Inventor: WU-DER YANG, TAOYUAN CITY (TW)

(21) Appl. No.: 18/223,175

(22) Filed: Jul. 18, 2023

Related U.S. Application Data
(62) Division of application No. 17/973,641, filed on Oct. 26, 2022.

(51) Int. Cl. H01L 23/498; H01L 23/00; H01L 23/31

(52) U.S. Cl. CPC H01L 23/49811; H01L 23/3128; H01L 23/49838; H01L 24/16; H01L 24/32; H01L 24/73; H01L 2224/16225; H01L 2224/32225; H01L 2224/73203

(57) ABSTRACT

A package structure and a method of manufacturing a package structure are provided. The package structure includes a substrate and an electronic component. The substrate includes a patterned circuit layer and defines a through hole. An extending portion of the patterned circuit layer extends along a sidewall of the through hole. The electronic component has an active surface over the through hole of the substrate. The active surface of the electronic component is electrically connected to the patterned circuit layer of the substrate through the extending portion of the patterned circuit layer in the through hole.

### CROSS-REFERENCE TO RELATED APPLICATION

This application is a divisional application of U.S. Non-Provisional application Ser. No. 17/973,641 filed 26 Oct. 2022, which is incorporated herein by reference in its entirety.

### TECHNICAL FIELD

The present disclosure relates to a package structure and a method for manufacturing a package structure, and more particularly, to a WBGA package structure.

### DISCUSSION OF THE BACKGROUND

In a window ball grid array (WBGA) package, a substrate may define a window over an electronic component. The electronic component may be electrically connected to the substrate through a wire-bonding process. That is, the electrical connection between the electronic component and the substrate may be accomplished by golden bonding wires in the window of the substrate. The advantage of such wire-bonding process is low cost. However, such WBGA package can not transmit high-frequency signals.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a package structure. The package structure includes a substrate and an electronic component. The substrate includes a patterned circuit layer and defines a through hole. An extending portion of the patterned circuit layer extends along a sidewall of the through hole. The electronic component has an active surface over the through hole of the substrate. The active surface of the electronic component is electrically connected to the patterned circuit layer of the substrate through the extending portion of the patterned circuit layer in the through hole.

Another aspect of the present disclosure provides a package structure. The package structure includes a substrate and an electronic component. The substrate includes a patterned circuit layer and defines a through hole. The electronic component is disposed corresponding to the through hole of the substrate. A portion of the patterned circuit layer is bent to extend through the through hole and to connect the electronic component.

Another aspect of the present disclosure provides a method of manufacturing a package structure. The method includes: providing a substrate having a first surface and a second surface opposite to the first surface, wherein the substrate includes a patterned circuit layer and defines a through hole, the patterned circuit layer is disposed adjacent to the second surface of the substrate, and an extending portion of the patterned circuit layer extends to a position corresponding to the through hole; disposing an electronic component on the first surface of the substrate; and pressing an end of the extending portion of the patterned circuit layer to contact the electronic component.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic cross-sectional view of a package structure in accordance with some embodiments of the present disclosure.

FIG. 1A is a schematic cross-sectional view of a package structure in accordance with some embodiments of the present disclosure.

FIG. 2 illustrates one or more stages of a method of manufacturing a package structure in accordance with some embodiments of the present disclosure.

FIG. 3 illustrates one or more stages of a method of manufacturing a package structure in accordance with some embodiments of the present disclosure.

FIG. 3A illustrates a schematic bottom view of a substrate in accordance with some embodiments of the present disclosure.

FIG. 4 illustrates a cross-sectional view taken along line A-A of FIG. 3.

FIG. 5 illustrates a top view of the substrate of FIG. 4.

FIG. 6 illustrates one or more stages of a method of manufacturing a package structure in accordance with some embodiments of the present disclosure.

FIG. 7 illustrates one or more stages of a method of manufacturing a package structure in accordance with some embodiments of the present disclosure.

FIG. 8 illustrates a bottom view of FIG. 7.

FIG. 9 illustrates one or more stages of a method of manufacturing a package structure in accordance with some embodiments of the present disclosure.

FIG. 10 illustrates one or more stages of a method of manufacturing a package structure in accordance with some embodiments of the present disclosure.

FIG. 11 illustrates one or more stages of a method of manufacturing a package structure in accordance with some embodiments of the present disclosure.

FIG. 12 illustrates one or more stages of a method of manufacturing a package structure in accordance with some embodiments of the present disclosure.

FIG. 13 illustrates one or more stages of a method of manufacturing a package structure in accordance with some embodiments of the present disclosure.

FIG. 14 illustrates one or more stages of a method of manufacturing a package structure in accordance with some embodiments of the present disclosure.

FIG. 15 illustrates one or more stages of a method of manufacturing a package structure in accordance with some embodiments of the present disclosure.

FIG. 16 illustrates one or more stages of a method of manufacturing a package structure in accordance with some embodiments of the present disclosure.

FIG. 17 illustrates one or more stages of a method of manufacturing a package structure in accordance with some embodiments of the present disclosure.

FIG. 18 illustrates one or more stages of a method of manufacturing a package structure in accordance with some embodiments of the present disclosure.

FIG. 19 illustrates a flow chart of a method of manufacturing a package structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

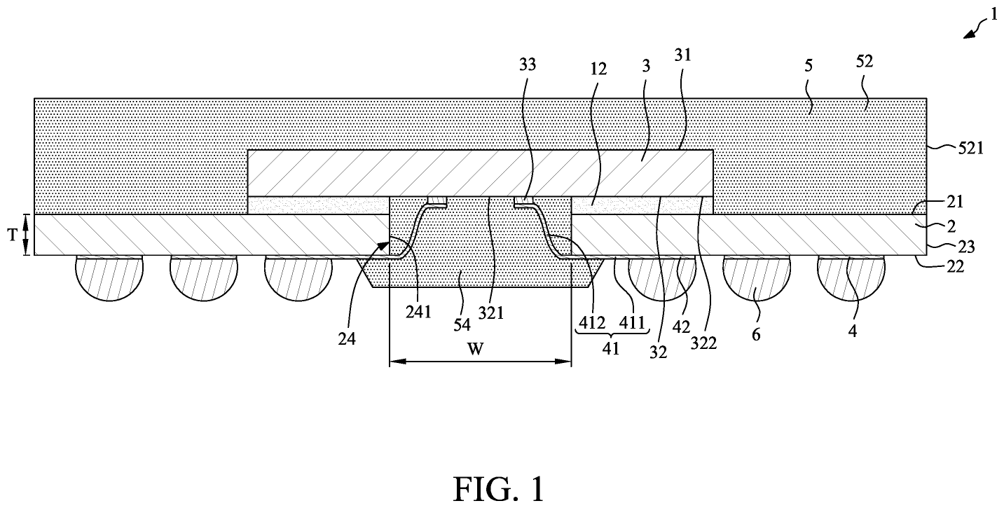

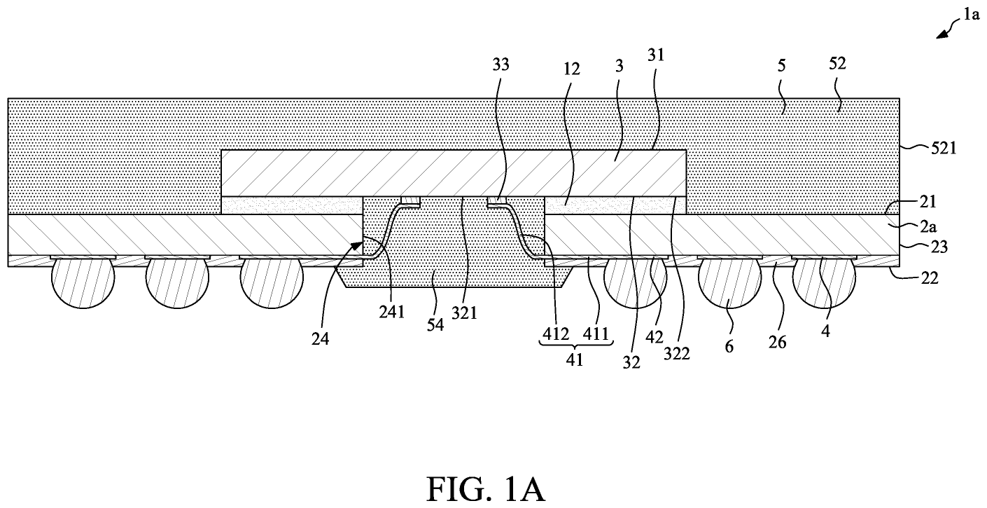

FIG. 1 is a schematic cross-sectional view of a package structure 1 in accordance with some embodiments of the present disclosure. The package structure 1 may be a window ball grid array (WBGA) package. As shown in FIG. 1, in some embodiments, the package structure 1 may include a substrate 2, an electronic component 3, a package body 5 and a plurality of external connectors 6.

In some embodiments, the substrate 2 may include semiconductor materials such as silicon, germanium, gallium, arsenic, and combinations thereof. In some embodiments, the substrate 2 may include organic material, glass, ceramic material or the like. For example, the substrate 2 may be made of a cured photoimageable dielectric (PID) material such as epoxy or polyimide (PI) including photoinitiators. For example, the substrate 2 may include a homogeneous material. For example, the material of the substrate 2 may include epoxy type FR5, FR4, Bismaleimide triazine (BT), print circuit board (PCB) material, Prepreg (PP), Ajinomoto build-up film (ABF) or other suitable materials.

The substrate 2 may have a first surface 21 (e.g., a top surface), a second surface 22 (e.g., a bottom surface) and a lateral surface 23. The second surface 22 (e.g., the bottom surface) may be opposite to the first surface 21 (e.g., the top surface). The lateral surface 23 may extend between the first surface 21 (e.g., the top surface) and the second surface 22 (e.g., the bottom surface). The substrate 2 may define a through hole 24 extending through the substrate 2. Thus, the sidewall 241 of the through hole 24 may extend between the first surface 21 (e.g., the top surface) and the second surface 22 (e.g., the bottom surface).

The substrate 2 may include a patterned circuit layer 4 disposed adjacent to the second surface 22 (e.g., the bottom surface) of the substrate 2. The patterned circuit layer 4 may be a fan-out circuit layer or a redistribution layer (RDL). The patterned circuit layer 4 may be disposed on the second surface 22 (e.g., the bottom surface) of the substrate 2. Alternatively, the patterned circuit layer 4 may be embedded in the substrate 2.

The patterned circuit layer 4 may include a plurality of conductive traces 41 and a plurality of bonding pads 42. Each of the traces 41 may connect to a respective one of the bonding pads 42. Each of the bonding pads 42 may be an input/output (I/O) terminal pad (such as a ball pad). A material of the patterned circuit layer 4 may include copper (Cu), silver (Ag), aluminum (Al), gold (Au), or an alloy thereof. For example, the patterned circuit layer 4 may be formed or patterned from a metal foil such as a copper foil. Thus, the conductive traces 41 and the bonding pads 42 may be formed concurrently and integrally through an etching process.

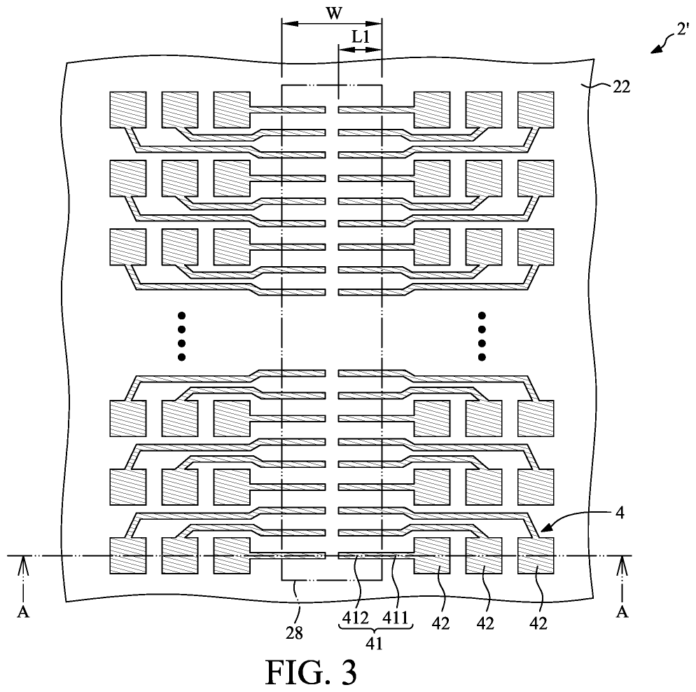

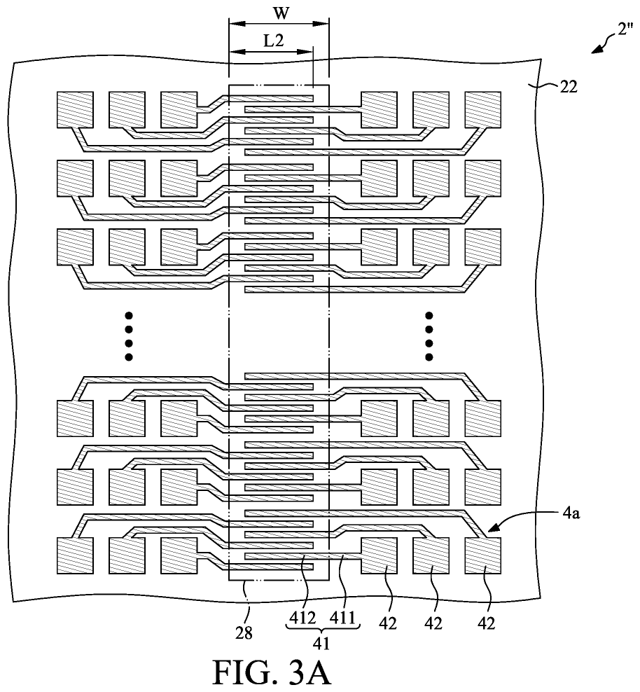

The conductive trace 41 may include a main portion 411 and an extending portion 412. The main portion 411 may be connected to the bonding pads 42. The extending portion 412 of the conductive trace 41 of the patterned circuit layer 4 and the patterned circuit layer 4 may be at the same layer. Alternatively, the extending portion 412 of the conductive trace 41 of the patterned circuit layer 4 and the patterned circuit layer 4 may be formed integrally. The extending portion 412 may be disposed in the through hole 24 of the substrate 2. As shown in FIG. 1, the extending portion 412 of the patterned circuit layer 4 may extend along the sidewall 241 of the through hole 24 of the substrate 2. In addition, the extending portion 412 of the patterned circuit layer 4 may be bent to extend through the through hole 24 and to physically connect and electrically connect the electronic component 3. A length L1 (FIG. 3) of the extending portion 412 of the conductive trace 41 of the patterned circuit layer 4 may be greater than a thickness T (FIG. 1) of the substrate 2. The length L1 (FIG. 3) of the extending portion 412 of the conductive trace 41 of the patterned circuit layer 4 may be less than one half of a width W (FIG. 3) of the through hole 24 of the substrate 2.

In some embodiments, the substrate 2 may include only one patterned circuit layer 4. Thus, there may be no further circuit layer disposed adjacent to the first surface 21 (e.g., the top surface) of the substrate 2 or disposed on the first surface 21 (e.g., the top surface) of the substrate 2. Further, there may be no inner (or vertical) electrical connection (or electrical path) within the substrate 2. There may be no inner (or vertical) conductive via embedded in the substrate 2. Thus, there may be no electrical connection between the first surface 21 of the substrate 2 and the second surface 22 of the substrate 2.

In some embodiments, the electronic component 3 may include a semiconductor die or a chip, such as a memory die (e.g., dynamic random access memory (DRAM) die, static random access memory (SRAM) die, etc.), a signal processing die (e.g., digital signal processing (DSP) die), a logic die (e.g., application processor (AP), system-on-a-chip (SoC), central processing unit (CPU), graphics processing unit (GPU), microcontroller, etc.), a power management die (e.g., power management integrated circuit (PMIC) die), a radio frequency (RF) die, a sensor die, a micro-electro-mechanical-system (MEMS) die, a front-end die (e.g., analog front-end (AFE) dies) or other active components.

The electronic component 3 may be disposed over the first surface 21 of the substrate 2, and may be attached to the first surface 21 of the substrate 2. The electronic component 3 may be disposed corresponding to the through hole 24 of the substrate 2. The electronic component 3 may have an active surface 32 (e.g., a second surface or a bottom surface) and a backside surface 31 (e.g., a first surface or a top surface). The active surface 32 (e.g., the second surface or the bottom surface) may face the substrate 2. The backside surface 31 (e.g., the first surface or the top surface) may be opposite to the active surface 32 and may face away from the substrate 2.

The active surface 32 of the electronic component 3 may have a first portion 321 and a second portion 322. The second portion 322 of the active surface 32 of the electronic component 3 may surround the first portion 321 of the active surface 32 of the electronic component 3. The first portion 321 of the active surface 32 of the electronic component 3 may be disposed over the through hole 24 of the substrate 2, and may be exposed in the through hole 24 of the substrate 2. The second portion 322 of the active surface 32 of the electronic component 3 may be adhered to the first surface 21 of the substrate 2 through an adhesion layer 12. In some embodiments, the adhesion layer 12 may include an adhesive material, such as epoxy, a die attach film (DAF), glue or the like.

The electronic component 3 may include at least one bump 33 disposed adjacent to the active surface 32 of the electronic component 3. The extending portion 412 of the conductive trace 41 of the patterned circuit layer 4 may be connected to the bump 33 of the electronic component 3. Thus, the active surface 32 of the electronic component 3 may be electrically connected to the patterned circuit layer 4 of the substrate 2 through the extending portion 412 of the conductive trace 41 of the patterned circuit layer 4 in the through hole 24. As shown in FIG. 1, the electronic component 3 may be electrically connected to the patterned circuit layer 4 solely through the bent portion (e.g., the extending portion 412 of the conductive trace 41) of the patterned circuit layer 4. There may be no electrical connection between the electronic component 3 and the first surface 21 of the substrate 2.

In some embodiments, the package body 5 may include molding material, such as a Novolac-based resin, an epoxy-based resin, a silicone-based resin, or another suitable encapsulant. Suitable fillers may also be included, such as powdered SiO₂. The package body 5 may include a first portion 52 and a second portion 54 formed concurrently and integrally. The first portion 52 may be disposed on the first surface 21 of the substrate 2, and may encapsulate the electronic component 3. The second portion 54 may be disposed in the through hole 24 of the substrate 2, and may encapsulate the extending portion 412 of the conductive trace 41 of the patterned circuit layer 4. In addition, the second portion 54 of the package body 5 may contact the first portion 321 of the active surface 32 of the electronic component 3. Thus, the package body 5 may encapsulate the bent portion (e.g., the extending portion 412 of the conductive trace 41) of the patterned circuit layer 4 and the electronic component 3.

The external connectors 6 may be disposed on the bonding pads 42 of the patterned circuit layer 4 to provide electrical connections, for example, I/O connections, of the substrate 2. For example, the external connector 6 may include or may be electrically connected to a ground reference node (GND) node, an electrical power node (VDD) node, a voltage node, or a signal node. In some embodiments, the external connector 6 may include a controlled collapse chip connection (C4) bump, a ball grid array (BGA) or a land grid array (LGA).

In the embodiment illustrated in FIG. 1, the substrate 2 may include only one patterned circuit layer 4. Thus, the cost of the substrate 2 may be reduced. In addition, since the extending portion 412 of the conductive trace 41 of the patterned circuit layer 4 and the patterned circuit layer 4 may be at the same layer, there may be no interface between the conductive trace 41 (including the extending portion 412) and the bonding pads 42. Thus, the package structure 1 may be used for transmitting high-frequency signals such as 8000 GHz data rate. In addition, the manufacturing process of the package structure 1 may be simplified, and the manufacturing cost of the package structure 1 may be reduced.

FIG. 1A is a schematic cross-sectional view of a package structure 1a in accordance with some embodiments of the present disclosure. The package structure 1a may be similar to the package structure 1 of FIG. 1, except for a structure of the substrate 2a. The substrate 2a may further include a dielectric layer 26, such as a solder resist layer. The dielectric layer 26 may cover the patterned circuit layer 4, and may define a plurality of openings to expose the bonding pads 42. As shown in FIG. 1A, the patterned circuit layer 4 may be embedded in the substrate 2a.

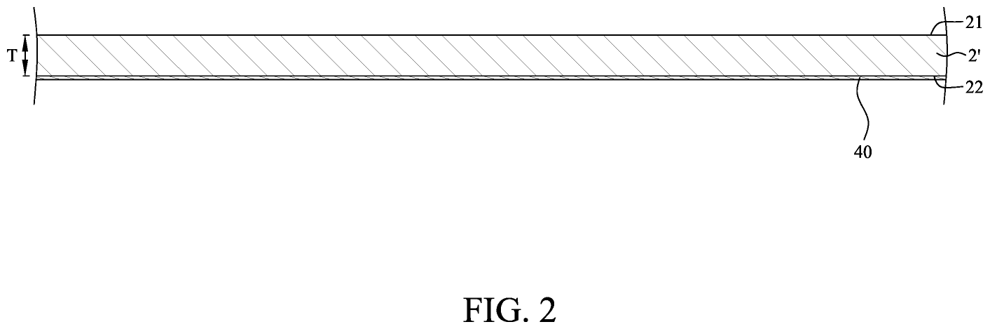

FIG. 2 to FIG. 18 illustrate stages of a method of manufacturing a package structure in accordance with some embodiments of the present disclosure. At least some of these figures have been simplified for a better understanding of the aspects of the present disclosure. In some embodiments, the package structure 1 in FIG. 1 may be manufactured by the operations described below with respect to FIG. 2 to FIG. 18.

Referring to FIG. 2, a substrate 2′ may be provided. The substrate 2′ may include semiconductor materials such as silicon, germanium, gallium, arsenic, and combinations thereof. In some embodiments, the substrate 2′ may include organic material, glass, ceramic material or the like. For example, the substrate 2′ may be made of a cured photoimageable dielectric (PID) material such as epoxy or polyimide (PI) including photoinitiators. For example, the substrate 2′ may include a homogeneous material. For example, the material of the substrate 2′ may include epoxy type FR5, FR4, Bismaleimide triazine (BT), print circuit board (PCB) material, Prepreg (PP), Ajinomoto build-up film (ABF) or other suitable materials.

The substrate 2′ may have a first surface 21 (e.g., a top surface) and a second surface 22 (e.g., a bottom surface). The second surface 22 (e.g., the bottom surface) may be opposite to the first surface 21 (e.g., the top surface). The substrate 2′ may have a thickness T. The substrate 2′ may include a metal foil 40 such as a copper foil on the second surface 22 (e.g., a bottom surface) of the substrate 2′. The metal foil 40 may be adhered or attached to the second surface 22 (e.g., a bottom surface) of the substrate 2′. Alternatively, the metal foil 40 may be provided on the second surface 22 (e.g., a bottom surface) of the substrate 2′. In some embodiments, the substrate 2′ may include only one metal foil 40. Thus, the substrate 2′ may be a single-sided substrate or a single-sided copper-clad substrate or a single-sided copper foil substrate. The cost of the single-sided substrate 2′ may be lower than the cost of a double-sided substrate including two metal foils disposed on a top surface and a bottom surface thereof respectively.

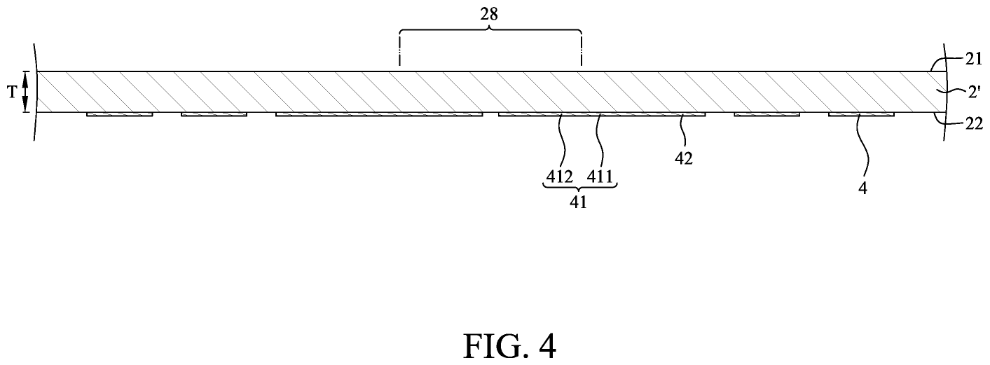

Referring to FIG. 3 and FIG. 4, wherein FIG. 4 illustrates a cross-sectional view taken along line A-A of FIG. 3, the metal foil 40 on the second surface 22 of the substrate 2′ may be patterned to form a patterned circuit layer 4. The patterning process may include: disposing a patterned mask on the metal foil 40 and then etching portions of the metal foil 40 that are exposed from the patterned mask. Thus, the patterned circuit layer 4 may be formed by etching rather than plating. The manufacturing cost of such patterning process may be reduced.

The substrate 2′ may have a predetermined area 28 corresponding to the through hole 24 of FIG. 1. The patterned circuit layer 4 may be a fan-out circuit layer or a redistribution layer (RDL). The patterned circuit layer 4 may be disposed on the second surface 22 (e.g., the bottom surface) of the substrate 2′. Alternatively, the patterned circuit layer 4 may be embedded in the substrate 2′. The patterned circuit layer 4 may include a plurality of conductive traces 41 and a plurality of bonding pads 42. Each of the traces 41 may connect to a respective one of the bonding pads 42. Each of the bonding pads 42 may be an input/output (I/O) terminal pad (such as a ball pad). A material of the patterned circuit layer 4 may include copper (Cu), silver (Ag), aluminum (Al), gold (Au), or an alloy thereof. The conductive traces 41 and the bonding pads 42 may be formed concurrently and integrally through the etching stage of the patterning process.

The conductive trace 41 may include a main portion 411 and an extending portion 412. The main portion 411 may be connected to the bonding pads 42. The extending portion 412 of the conductive trace 41 of the patterned circuit layer 4 and the patterned circuit layer 4 may be at the same layer. The extending portion 412 may be disposed in the predetermined area 28 of the substrate 2′. A length L1 of the extending portion 412 of the conductive trace 41 of the patterned circuit layer 4 may be greater than the thickness T of the substrate 2′. The length L1 of the extending portion 412 of the conductive trace 41 of the patterned circuit layer 4 may be less than one half of a width W of the predetermined area 28 of the substrate 2′.

An extending direction of an extending portion 412 may be substantially aligned with an extending direction of an opposite extending portion. Thus, an end surface of the extending portion 412 may face an end surface of the opposite extending portion. For example, as shown in FIG. 3, an extending direction of the bottom right extending portion 412 may be substantially aligned with an extending direction of the bottom left extending portion 412. Thus, an end surface of the bottom right extending portion 412 may face an end surface of the bottom left extending portion 412.

FIG. 3A illustrates a schematic bottom view of a substrate 2″ in accordance with some embodiments of the present disclosure. The substrate 2″ may be similar to the substrate 2′ of FIG. 3, except for the positions of the extending portion 412 of the conductive trace 41 of the patterned circuit layer 4a. An extending direction of an extending portion 412 may be not substantially aligned with an extending direction of an opposite extending portion. Thus, an end surface of the extending portion 412 may not face an end surface of the opposite extending portion. For example, as shown in FIG. 3A, an extending direction of the bottom right extending portion 412 may be misaligned with an extending direction of the bottom left extending portion 412. Thus, an end surface of the bottom right extending portion 412 may not face an end surface of the bottom left extending portion 412. In addition, the length L2 of the extending portion 412 of the conductive trace 41 of the patterned circuit layer 4a may be greater than one half of the width W of the predetermined area 28 of the substrate 2′.

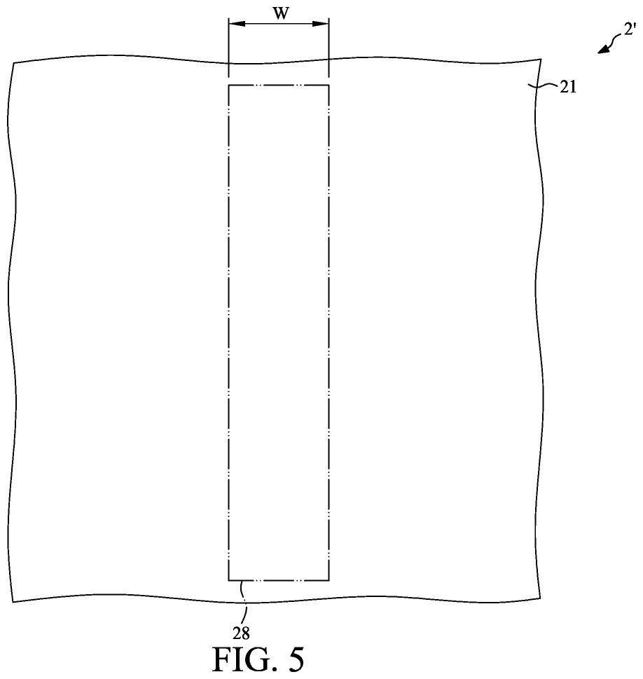

Referring to FIG. 5, a top view of the substrate 2′ of FIG. 4 is illustrated. There may be no patterned circuit layer or conductive metal layer on the first surface 21 (e.g., the top surface) of the substrate 2′.

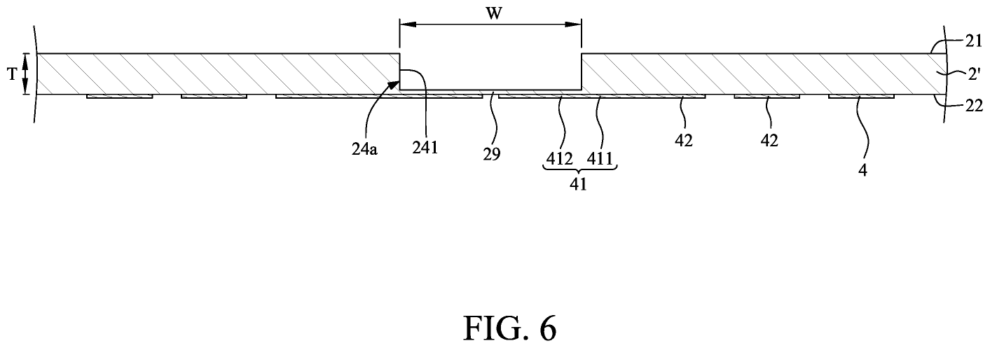

Referring to FIG. 6, a portion of the substrate 2′ in the predetermined area 28 may be removed from the first surface 21 (e.g., the top surface) by, for example, milling or etching, so as to form a cavity 24a. The cavity 24a may be recessed from the first surface 21 (e.g., the top surface), and may not extend through the substrate 2′. The size of the cavity 24a may correspond to the size of the predetermined area 28. The cavity 24a may have a sidewall 241. Meanwhile, a small portion 29 of the substrate 2′ may remain to protect the extending portions 412 of the conductive traces 41 of the patterned circuit layer 4. The top surface of the small portion 29 may be a bottom wall of the cavity 24a.

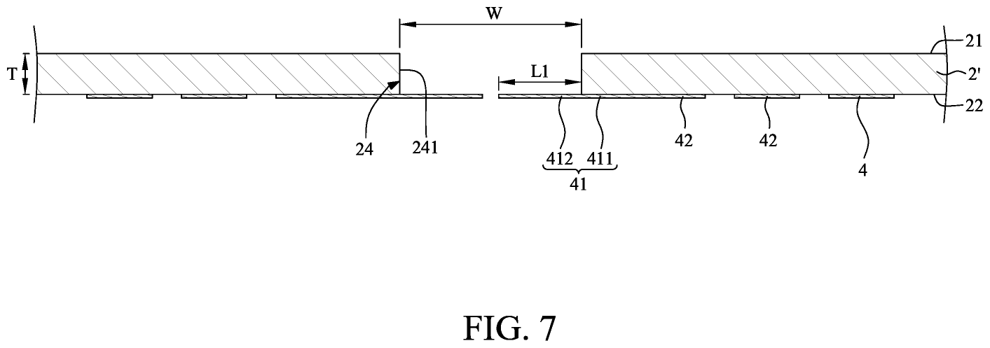

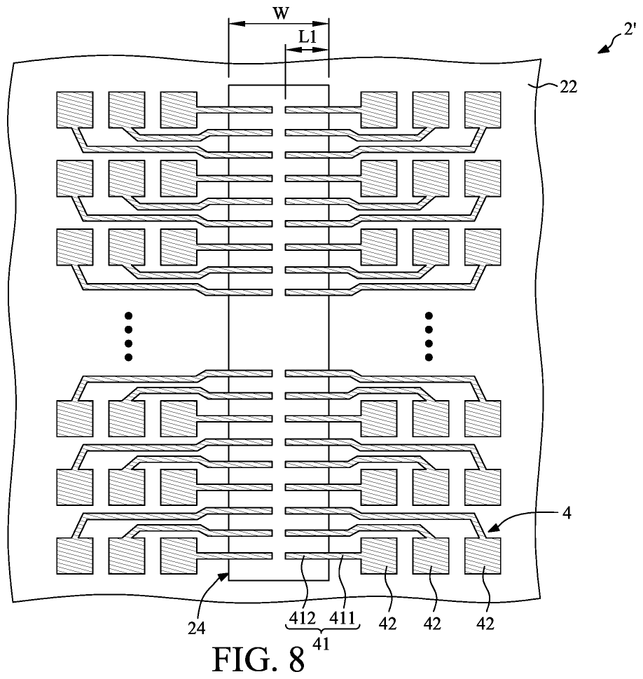

Referring to FIG. 7 and FIG. 8, wherein FIG. 8 illustrates a bottom view of FIG. 7, the small portion 29 of the substrate 2′ may be removed by, for example, laser so as to form a through hole 24. The through hole 24 may extend through the substrate 2. Thus, the sidewall 241 of the through hole 24 may extend between the first surface 21 (e.g., the top surface) and the second surface 22 (e.g., the bottom surface). The extending portion 412 of the conductive traces 41 of the patterned circuit layer 4 may be disposed corresponding to the through hole 24 of the substrate 2. Thus, the extending portion 412 of the conductive traces 41 of the patterned circuit layer 4 may be exposed from the through hole 24 of the substrate 2. The length L1 of the extending portion 412 of the conductive trace 41 of the patterned circuit layer 4 may be less than one half of a width W of the through hole 24 of the substrate 2′.

In some embodiments, the through hole 24 of the substrate 2′ may be formed in a single stage. That is, a portion of the substrate 2′ may be removed from the first surface 21 of the substrate 2′ to form the through hole 24 and to expose the extending portion 412 of the patterned circuit layer 4.

Meanwhile, the substrate 2′ may include the patterned circuit layer 4 and may define the through hole 24. The patterned circuit layer 4 may be disposed adjacent to the second surface 22 of the substrate 2′. The extending portion 412 of the patterned circuit layer 4 may extend to a position corresponding to the through hole 24.

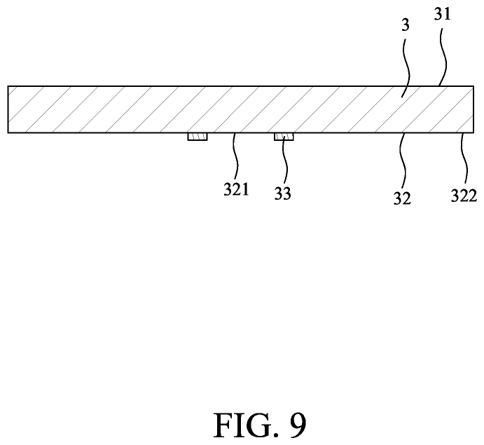

Referring to FIG. 9, an electronic component 3 may be provided. The electronic component 3 may include a semiconductor die or a chip, such as a memory die (e.g., dynamic random access memory (DRAM) die, static random access memory (SRAM) die, etc.), a signal processing die (e.g., digital signal processing (DSP) die), a logic die (e.g., application processor (AP), system-on-a-chip (SoC), central processing unit (CPU), graphics processing unit (GPU), microcontroller, etc.), a power management die (e.g., power management integrated circuit (PMIC) die), a radio frequency (RF) die, a sensor die, a micro-electro-mechanical-system (MEMS) die, a front-end die (e.g., analog front-end (AFE) dies) or other active components.

The electronic component 3 may have an active surface 32 (e.g., a second surface or a bottom surface) and a backside surface 31 (e.g., a first surface or a top surface). The backside surface 31 (e.g., the first surface or the top surface) may be opposite to the active surface 32 (e.g., the second surface or the bottom surface). The active surface 32 of the electronic component 3 may have a first portion 321 and a second portion 322. The second portion 322 of the active surface 32 of the electronic component 3 may surround the first portion 321 of the active surface 32 of the electronic component 3. The electronic component 3 may include at least one bump 33 disposed adjacent to the active surface 32 of the electronic component 3. The bump 33 may be disposed on the first portion 321 of the active surface 32 of the electronic component 3.

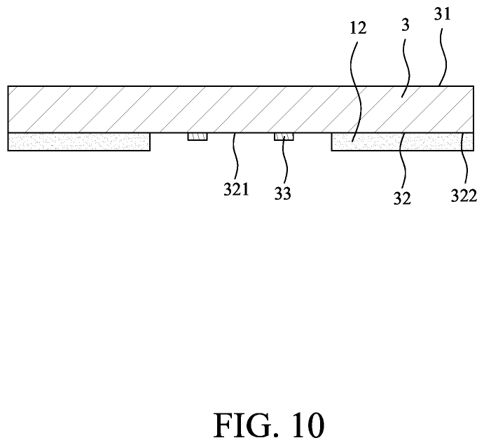

Referring to FIG. 10, an adhesion layer 12 may be formed or disposed on the second portion 322 of the active surface 32 of the electronic component 3. In some embodiments, the adhesion layer 12 may include an adhesive material, such as epoxy, a die attach film (DAF), glue or the like. The adhesion layer 12 may be disposed around the bump 33. The adhesion layer 12 may be at the periphery of the electronic component 3.

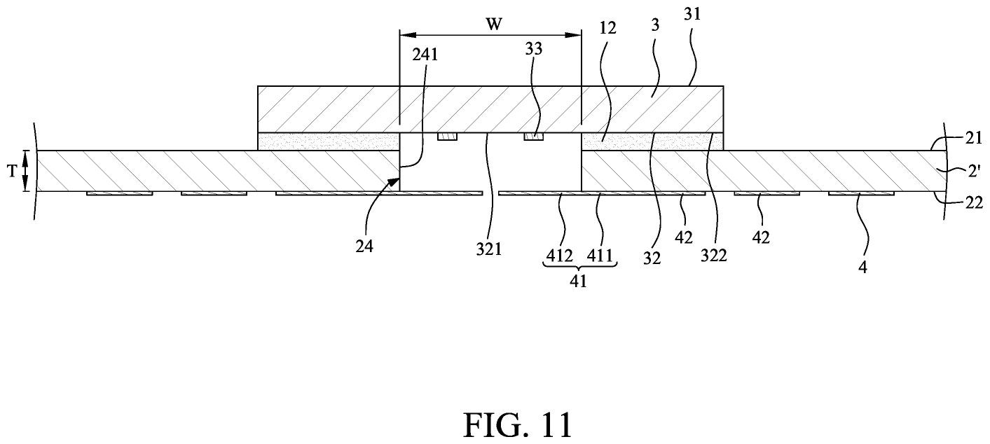

Referring to FIG. 11, the electronic component 3 may be disposed on the first surface 21 of the substrate 2′. Alternatively, the electronic component 3 may be disposed over the first surface 21 of the substrate 2′, and may be attached to the first surface 21 of the substrate 2′. The second portion 322 of the active surface 32 of the electronic component 3 may be adhered to the first surface 21 of the substrate 2′ through the adhesion layer 12. The electronic component 3 may be disposed corresponding to the through hole 24 of the substrate 2′. The active surface 32 (e.g., the second surface or the bottom surface) of the electronic component 3 may face the substrate 2′. The backside surface 31 (e.g., the first surface or the top surface) of the electronic component 3 may face away from the substrate 2′.

The first portion 321 of the active surface 32 of the electronic component 3 may be disposed over the through hole 24 of the substrate 2′, and may be exposed in the through hole 24 of the substrate 2′. Thus, the through hole 24 of the substrate 2′ may be located between the extending portion 412 of the conductive trace 41 of the patterned circuit layer 4 and the bump 33 of the electronic component 3.

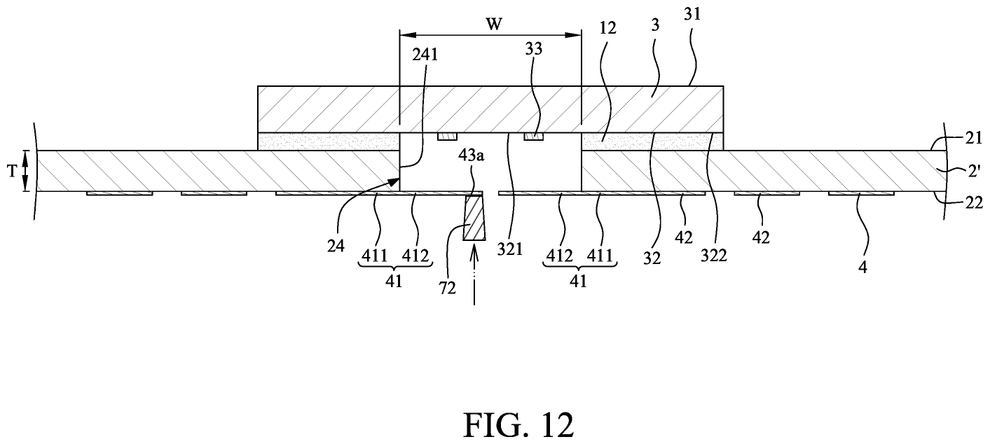

Referring to FIG. 12, a press head 72 may be provided to contact an end 43a of the extending portion 412 of the conductive trace 41 of the patterned circuit layer 4.

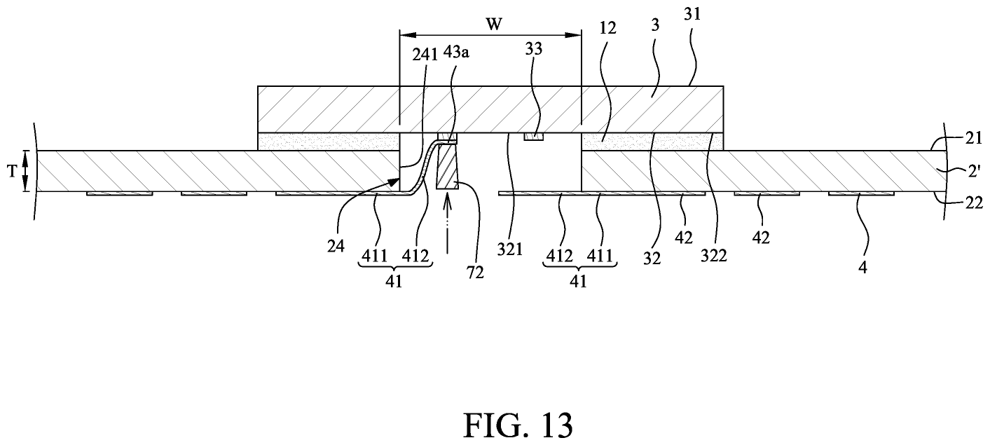

Referring to FIG. 13, the press head 72 may move toward the electronic component 3. Thus, the end 43a of the extending portion 412 of the patterned circuit layer 4 may be pressed to move through the through hole 24 of the substrate 2′ to contact the bump 33 of the electronic component 3. Then, the end 43a of the extending portion 412 of the patterned circuit layer 4 may be connected or bonded to the bump 33 of the electronic component 3 by ultrasonic welding or ultrasonic bonding. Meanwhile, the extending portion 412 of the patterned circuit layer 4 may be bent, and there may be an inclination angle between be the extending portion 412 of the conductive trace 41 and the main portion 411 of the conductive trace 41. For example, the inclination angle may be 100 degrees to 135 degrees.

As shown in FIG. 13, the extending portion 412 of the patterned circuit layer 4 may extend along the sidewall 241 of the through hole 24 of the substrate 2′. In addition, the extending portion 412 of the patterned circuit layer 4 may be bent to extend through the through hole 24 and to physically connect and electrically connect the bump 33 of the electronic component 3.

The end 43a of the extending portion 412 of the conductive trace 41 of the patterned circuit layer 4 may be connected to the bump 33 of the electronic component 3. Thus, the active surface 32 of the electronic component 3 may be electrically connected to the patterned circuit layer 4 of the substrate 2′ through the extending portion 412 of the conductive trace 41 of the patterned circuit layer 4 in the through hole 24.

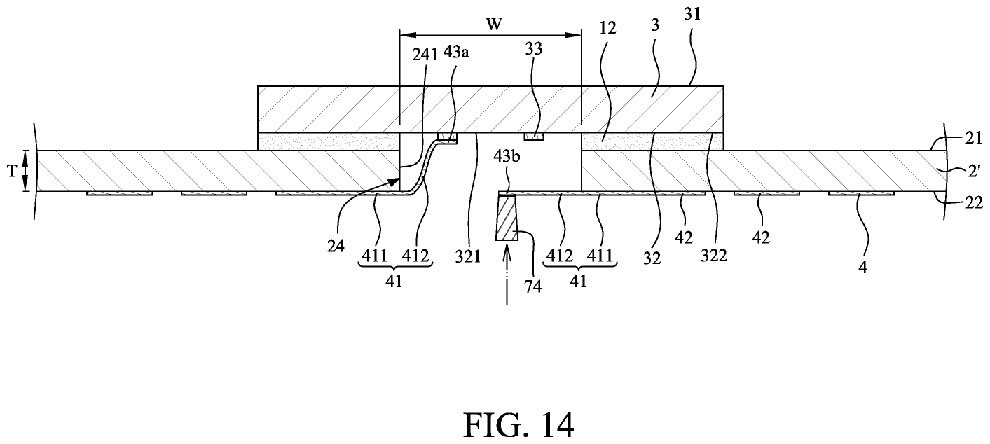

Referring to FIG. 14, the press head 72 may be removed. A press head 74 may be provided to contact an end 43b of the extending portion 412 of the conductive trace 41 of the patterned circuit layer 4. The press head 74 of FIG. 14 may be same as or different from the press head 72 of FIG. 12.

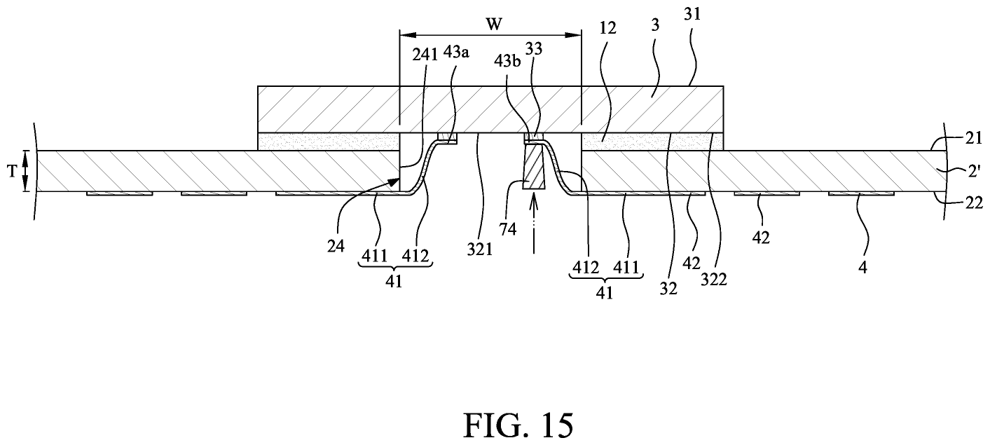

Referring to FIG. 15, the press head 74 may move toward the electronic component 3. Thus, the end 43b of the extending portion 412 of the patterned circuit layer 4 may be pressed to move through the through hole 24 of the substrate 2′ to contact the bump 33 of the electronic component 3. Then, the end 43b of the extending portion 412 of the patterned circuit layer 4 may be connected or bonded to the bump 33 of the electronic component 3 by ultrasonic welding or ultrasonic bonding. Meanwhile, the extending portion 412 of the patterned circuit layer 4 may be bent, and there may be an inclination angle between be the extending portion 412 of the conductive trace 41 and the main portion 411 of the conductive trace 41. For example, the inclination angle may be 100 degrees to 135 degrees.

The end 43b of the extending portion 412 of the conductive trace 41 of the patterned circuit layer 4 may be connected to the bump 33 of the electronic component 3. Thus, the active surface 32 of the electronic component 3 may be electrically connected to the patterned circuit layer 4 of the substrate 2′ through the extending portion 412 of the conductive trace 41 of the patterned circuit layer 4 in the through hole 24. As shown in FIG. 15, the electronic component 3 may be electrically connected to the patterned circuit layer 4 solely through the bent portion (e.g., the extending portion 412 of the conductive trace 41) of the patterned circuit layer 4. There may be no electrical connection between the electronic component 3 and the first surface 21 of the substrate 2.

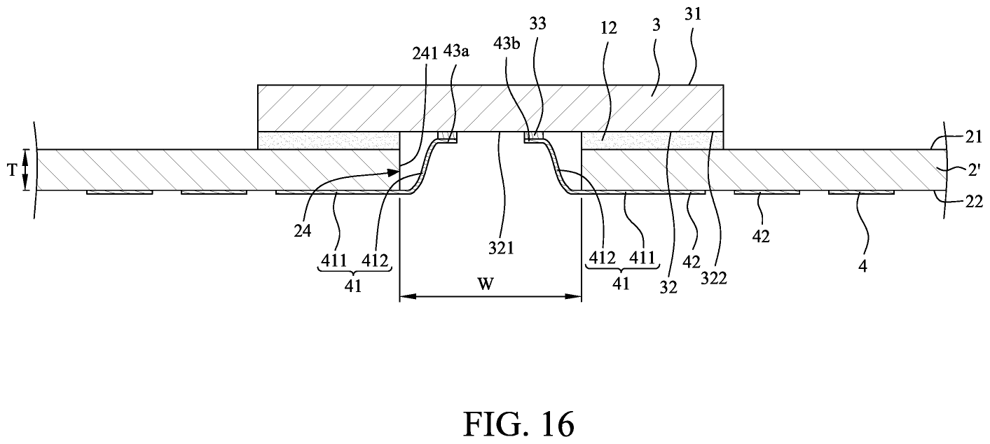

Referring to FIG. 16, the press head 74 may be removed.

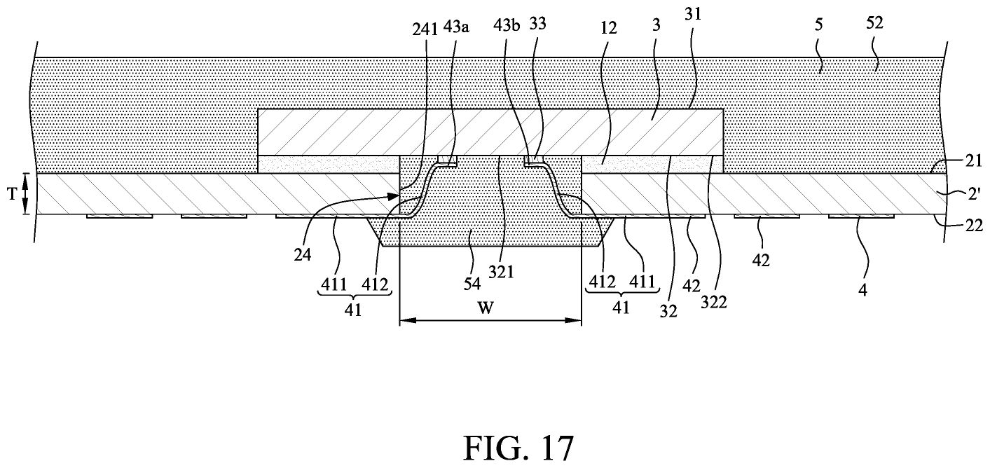

Referring to FIG. 17, a package body 5 may be formed or disposed to encapsulate the extending portion 412 of the patterned circuit layer 4 and the electronic component 3. In some embodiments, the package body 5 may be formed by a molding technique, such as transfer molding or compression molding. In some embodiments, the package body 5 may include molding material, such as a Novolac-based resin, an epoxy-based resin, a silicone-based resin, or another suitable encapsulant. Suitable fillers may also be included, such as powdered SiO₂. The package body 5 may include a first portion 52 and a second portion 54 formed concurrently and integrally. The first portion 52 may be disposed on the first surface 21 of the substrate 2′, and may encapsulate the electronic component 3. The second portion 54 may be disposed in the through hole 24 of the substrate 2′, and may encapsulate the extending portion 412 of the conductive trace 41 of the patterned circuit layer 4. In addition, the second portion 54 of the package body 5 may contact the first portion 321 of the active surface 32 of the electronic component 3. Thus, the package body 5 may encapsulate the bent portion (e.g., the extending portion 412 of the conductive trace 41) of the patterned circuit layer 4 and the electronic component 3.

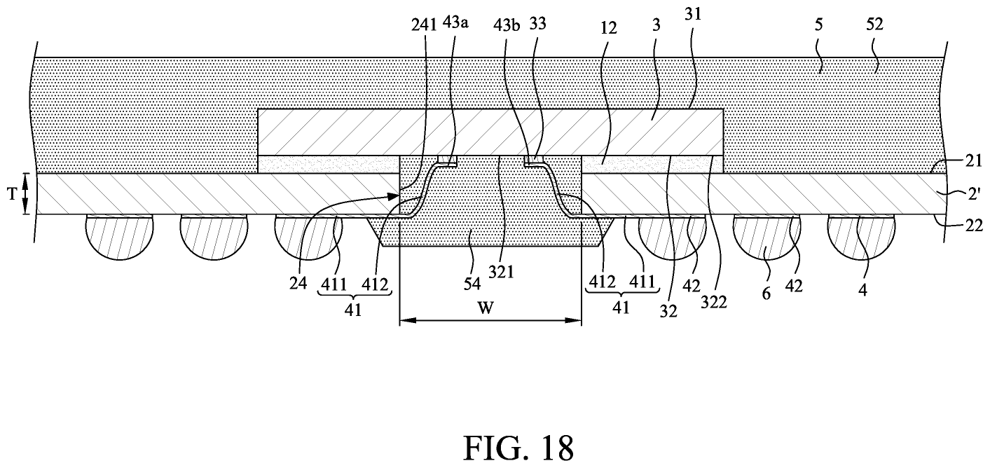

Referring to FIG. 18, one or more external connectors 6 may be formed or disposed on the bonding pads 42 of the patterned circuit layer 4 to provide electrical connections, for example, I/O connections, of the substrate 2′. For example, the external connector 6 may include or may be electrically connected to a ground reference node (GND) node, an electrical power node (VDD) node, a voltage node, or a signal node. In some embodiments, the external connector 6 may include a controlled collapse chip connection (C4) bump, a ball grid array (BGA) or a land grid array (LGA). In some embodiments, the operation of forming the external connectors 6 may be conducted before the operation of forming the package body 5.

Them a singulation process may be conducted to form the package structure 1 of FIG. 1.

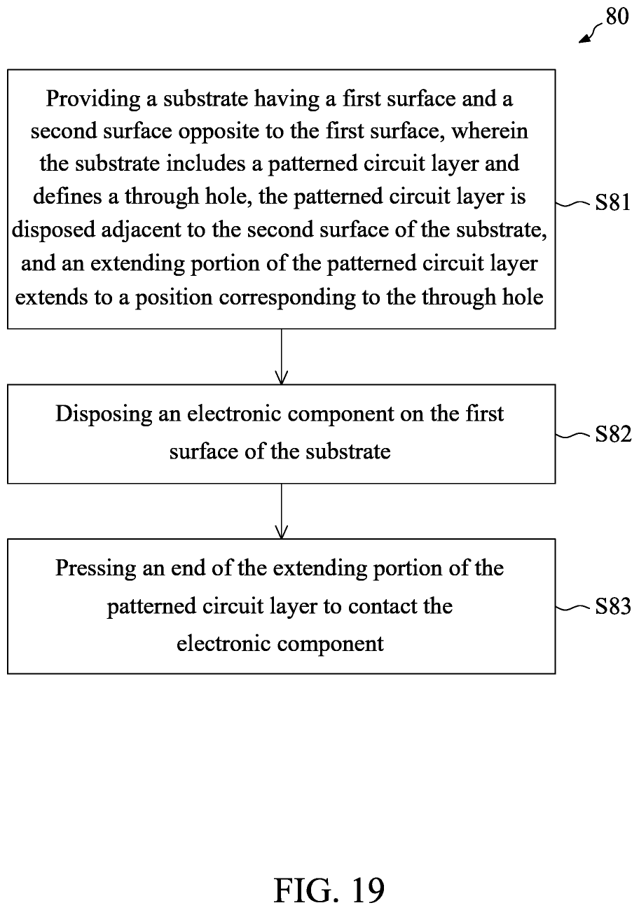

FIG. 19 illustrates a flow chart of a method 80 of manufacturing a package structure 1 in accordance with some embodiments of the present disclosure.

The step or operation S81 is providing a substrate having a first surface and a second surface opposite to the first surface, wherein the substrate includes a patterned circuit layer and defines a through hole, the patterned circuit layer is disposed adjacent to the second surface of the substrate, and an extending portion of the patterned circuit layer extends to a position corresponding to the through hole. For example, as shown in FIG. 7, a substrate 2′ is provided. The substrate 2′ has a first surface 21 and a second surface 22 opposite to the first surface 21. The substrate 2′ includes a patterned circuit layer 4 and defines a through hole 24. The patterned circuit layer 4 is disposed adjacent to the second surface 22 of the substrate 2′. An extending portion 412 of the patterned circuit layer 4 extends to a position corresponding to the through hole 24.

The step or operation S82 is disposing an electronic component on the first surface of the substrate. For example, as shown in FIG. 11, an electronic component 3 is disposed on the first surface 21 of the substrate 2′.

The step or operation S83 is pressing an end of the extending portion of the patterned circuit layer to contact the electronic component. For example, as shown in FIG. 13, the end 43a of the extending portion 412 of the patterned circuit layer 4 is pressed to contact the bump 33 of the electronic component 3.

One aspect of the present disclosure provides a package structure. The package structure includes a substrate and an electronic component. The substrate includes a patterned circuit layer and defines a through hole. An extending portion of the patterned circuit layer extends along a sidewall of the through hole. The electronic component has an active surface over the through hole of the substrate. The active surface of the electronic component is electrically connected to the patterned circuit layer of the substrate through the extending portion of the patterned circuit layer in the through hole.

Another aspect of the present disclosure provides a package structure. The package structure includes a substrate and an electronic component. The substrate includes a patterned circuit layer and defines a through hole. The electronic component is disposed corresponding to the through hole of the substrate. A portion of the patterned circuit layer is bent to extend through the through hole and to connect the electronic component.

Another aspect of the present disclosure provides a method of manufacturing a package structure. The method includes: providing a substrate having a first surface and a second surface opposite to the first surface, wherein the substrate includes a patterned circuit layer and defines a through hole, the patterned circuit layer is disposed adjacent to the second surface of the substrate, and an extending portion of the patterned circuit layer extends to a position corresponding to the through hole; disposing an electronic component on the first surface of the substrate; and pressing an end of the extending portion of the patterned circuit layer to contact the electronic component.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A package structure, comprising:
a substrate including a patterned circuit layer and defining a through hole, wherein an extending portion of the patterned circuit layer extends along a sidewall of the through hole;
an electronic component having an active surface over the through hole of the substrate, wherein the active surface of the electronic component is electrically connected to the patterned circuit layer of the substrate through the extending portion of the patterned circuit layer in the through hole; and
a package body disposed in the through hole of the substrate and encapsulating the extending portion of the patterned circuit layer, wherein the package body contacts the active surface of the electronic component;
wherein the substrate has a first surface and a second surface opposite to the first surface, the electronic component is attached to the first surface of the substrate;
wherein the electronic component includes at least one bump disposed adjacent to the active surface thereof, and the extending portion of the patterned circuit layer is connected to the at least one bump of the electronic component.

2. The package structure of claim 1, wherein the active surface of the electronic component has a first portion and a second portion, the first portion of the active surface of the electronic component is exposed in the through hole of the substrate, and the second portion of the active surface of the electronic component is adhered to the first surface of the substrate through an adhesion layer.

3. The package structure of claim 2, wherein the second portion of the active surface of the electronic component surrounds the first portion of the active surface of the electronic component.

4. The package structure of claim 1, wherein the patterned circuit layer is disposed adjacent to the second surface of the substrate.

5. The package structure of claim 1, wherein the package body is further disposed on the first surface of the substrate and encapsulating the electronic component.

6. The package structure of claim 1, wherein the extending portion of the patterned circuit layer and the patterned circuit layer are at the same layer.

7. The package structure of claim 1, wherein the extending portion of the patterned circuit layer and the patterned circuit layer are formed integrally.

8. The package structure of claim 1, further comprising:
at least one external connector disposed on the patterned circuit layer.

9. The package structure of claim 1, wherein the patterned circuit layer is formed from a metal foil.

10. The package structure of claim 1, wherein a length of the extending portion of the patterned circuit layer is greater than a thickness of the substrate.

11. A method of manufacturing a package structure, comprising:
providing a substrate having a first surface and a second surface opposite to the first surface, wherein the substrate includes a patterned circuit layer and defines a through hole, the patterned circuit layer is disposed adjacent to the second surface of the substrate, and an extending portion of the patterned circuit layer extends to a position corresponding to the through hole;
disposing an electronic component to the first surface of the substrate; and
pressing an end of the extending portion of the patterned circuit layer to contact the electronic component.

12. The method of claim 11, wherein providing the substrate includes:
providing a metal foil on a second surface of the substrate;
patterning the metal foil to form a patterned circuit layer;
removing a portion of the substrate from a first surface of the substrate to form a through hole and expose the extending portion of the patterned circuit layer.

13. The method of claim 12, wherein a length of the extending portion of the patterned circuit layer is greater than a thickness of the substrate.

14. The method of claim 12, wherein pressing the end of the extending portion of the patterned circuit layer includes pressing the end of the extending portion of the patterned circuit layer to move through the through hole of the substrate.

15. The method of claim 12, further comprising:
forming a package body to encapsulate the extending portion of the patterned circuit layer and the electronic component.
